(19) United States
(12) Patent Application Publication
(10) Pub. No.: US 2011/0147950 A1
(43) Pub. Date: Jun. 23, 2011

(54) METALLIZATION LAYER STRUCTURE FOR FLIP CHIP PACKAGE

(76) Inventors: Fong-Cheng Tai, Kaohsiung County (TW); Chi-Yang Yu, Taoyuan County (TW); Jeng-Gong Duh, Hsinchu City (TW)

(21) Appl. No.: 12/645,150

(22) Filed: Dec. 22, 2009

(51) Int. Cl. H01L 23/485

(52) U.S. Cl. 257/778; 257/E23.02

(57) ABSTRACT

The present invention discloses a metallization layer structure for flip chip package, which comprises an UBM layer formed on a metal pad, whereby a fine-quality tin-based solder ball can be formed on the metal pad. The UBM layer is a NiZnP layer formed via the reduction and oxidization of a solution containing nickel sulfate (Ni₂SO₄), zinc sulfate (ZnSO₄), sodium dihydrogen phosphite (NaH₂PO₂), sodium citrate dihydrate (Na₃C₆H₅O₇-2H₂O), and ammonium chloride (NH₄Cl). The present invention replaces the conventional Au/Ni—P dual-layer structure. Therefore, the present invention can decrease the complexity of the process and reduce the cost. Further, the metallization layer structure of the present invention is tough, hard to peel off and highly corrosion-resistant.

### FIELD OF THE INVENTION

The present invention relates to a structure for flip chip package, particularly to a metallization layer structure for flip chip package.

### BACKGROUND OF THE INVENTION

In electronic package, the first stage packaging process, which connects a chip to a carrier, may be categorized into three package types, which are the wire-bonding technique, the TAB (Tape Automatic Bonding) technique, and the F/C (Flip Chip) bonding technique.

The wire-bonding technique has a bottleneck in the time consumed. Further, the wire-bonding or the TAB technique packages greater volume electronic components, which conflicts with the current tendency to pursue slim and lightweight electronic products. Thus the F/C bonding technique was developed.

The F/C bonding technique is to achieve high I/O pins, superior heat dissipation and compactness of an electronic package. Further, comparing with the wire-bonding technique, the F/C bonding technique greatly reduces the length of the connection lines and effectively accelerates the transmission speed of electronic signals. Therefore, the F/C bonding technique has been the mainstream of the high-density electronic package technologies.

Refer to FIG. 1 for a conventional electronic component, which includes a chip 1 and a substrate 3. The chip 1 has a plurality of metal pads 2. The metal pad 2 is usually an aluminum pad or a copper pad. The substrate 3 has a plurality of connection points 4. A plurality of tin-based solder balls 5 are formed between the metal pads 2 and the connection points 4, whereby the chip 1 is electrically connected to the substrate 3 via the metal pads 2, tin-based solder balls 5 and connection points 4. A resin layer 6 may be disposed between the chip 1 and the substrate 3 to prevent from humidity and mechanical stress damage.

The process to form the abovementioned structure includes forming the tin-based solder balls 5 on the metal pads 2, flipping the chip 1 and joining the tin-based solder balls 5 to the connection points 4. Thus, the quality of the tin-based solder balls 5 directly influences the yield of electronic package.

Refer to FIG. 2. In order to form the tin-based solder balls 5 on the metal pads 2, multiple layers of metal films are coated on the metal pads 2 to form the so-called UBM 7 (Under-Bump Metallization). UBM 7 usually contains three metal layers, including an adhesion layer 8, a wetting layer 9 and a protective layer 10. The adhesion layer 8 is made of titanium, chromium, a titanium-tungsten alloy, or zinc. The adhesion layer 8 is to enhance the adherence of the metal pads 2 to the wetting layer 9. Therefore, the adhesion layer 8 is optional and used according to the characteristics of the materials of the metal pads 2 and the wetting layer 9. The wetting layer 9 is made of a metal able to effectively wet the tin-based solder balls 5, such as nickel, a nickel-phosphorus alloy, or copper, whereby the molten tin-based solder can remain on the wetting layer 9 and solidify to form a solder ball in a reflow soldering process. The protective layer 10 is made of a passive low-resistance metal, such as gold, to protect UBM 7 from being oxidized.

In the conventional UBM 7, the protective layer 10 is formed with a gold-plating process. However, the materials and equipment of the gold-plating process is expensive. Further, the gold film is hard to thicken or adhere to UBM 7 but easy to shatter or peel off. Therefore, the gold-plating process has been a bottleneck of the F/C package process.

### SUMMARY OF THE INVENTION

The primary objective of the present invention is to provide an under-bump metallization layer, which is easy to fabricate, low-cost, tough, hard to peel off and corrosion-resistant.

To achieve the abovementioned objective, the present invention proposes a metallization layer structure for flip chip package, which comprises an under-bump metallization (UBM) layer, wherein a nickel-zinc-phosphorus layer is coated on a metal pad to form the UBM layer, whereby a fine-quality tin-based solder ball can be formed on the metal pad.

Distinct from the conventional Au/Ni—P dual layer structure, the UBM layer of the present invention is a single NiZnP coated layer. Therefore, the present invention is easy to fabricate, low-cost, hard to shatter, and hard to peel off.

### BRIEF DESCRIPTION OF THE DRAWINGS

FIG. 1 is a sectional view schematically showing the structure of a conventional electronic component;

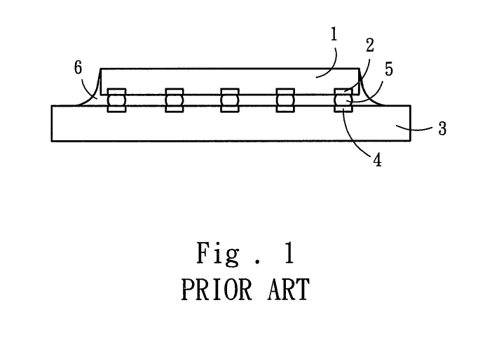

FIG. 2 is a sectional view schematically showing the structure of a conventional UBM;

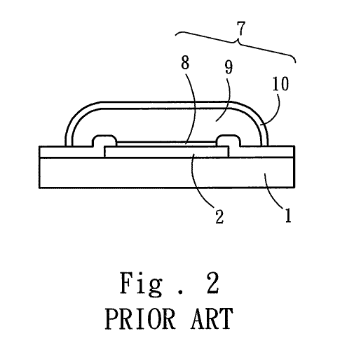

FIG. 3 is a sectional view schematically showing a metallization layer structure for flip chip package according to one embodiment of the present invention;

FIG. 4 is a sectional view schematically showing a metallization layer structure for flip chip package according to another embodiment of the present invention; and

FIG. 5 is a micrograph showing the microstructure of a tin-based solder ball and an UBM layer according to the present invention.

### DETAILED DESCRIPTION OF THE PREFERRED EMBODIMENTS

The technical contents of the present invention will be described in detail with the embodiments. However, it should be understood that the embodiments are only to exemplify the present invention but not to limit the scope of the present invention.

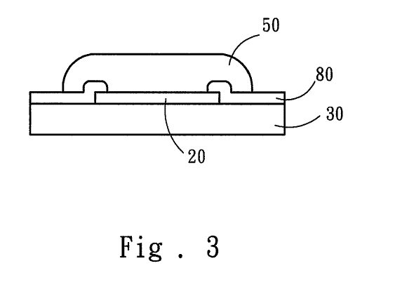

Refer to FIG. 3. The present invention proposes a metallization layer structure for flip chip package, which is formed on a metal pad 20. The metal pad 20 is formed on a chip 30. A passive protective layer 80 is also formed on the chip 30 to protect the chip 30, but the passive protective layer 80 exposes the metal pad 20. The metal pad 20 is made of a metal selected from the group consisting of aluminum and copper, which is usually used to form the connection points. The present invention comprises an UBM (Under-Bump Metallization) layer 50, which is a NiZnP coated layer formed on the metal pad 20.

The NiZnP UBM layer 50 can be formed via the reduction and oxidization of a solution containing nickel sulfate (Ni₂SO₄), zinc sulfate (ZnSO₄), sodium dihydrogen phosphite (NaH₂PO₂), sodium citrate dihydrate (Na₃C₆H₅O₇-2H₂O), and ammonium chloride (NH₄Cl) with a preferred proportion thereof being 40 g of Ni₂SO₄, 3 g of ZnSO₄, 11 g of NaH₂PO₂, 60 g of Na₃C₆H₅O₇-2H₂O, and 80 g of NH₄Cl in each liter of solution.

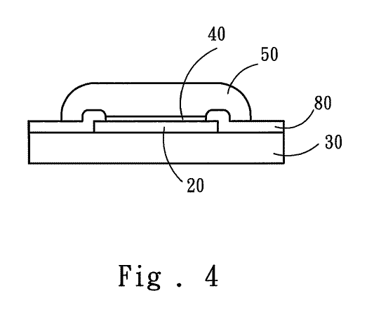

Refer to FIG. 4 for another embodiment of the present invention. In this embodiment, the metallization layer structure comprises an adhesion layer 40 and an UBM layer 50, wherein the adhesion layer 40 is formed on the metal pad 20, and the UBM layer 50 is formed on the adhesion layer 40. The adherence of the adhesion layer 40 can enhance the integration stability of the UBM layer 50 and the metal pad 20. The UBM layer 50 is also a NiZnP coated layer in this embodiment.

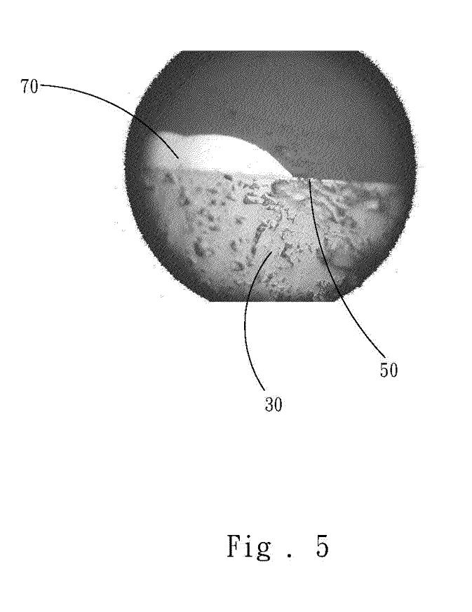

Refer to FIG. 5. Via the reduction and oxidization of the abovementioned solution, a NiZnP coated layer is formed to function as the UBM layer 50, and the NiZnP coated layer contains nickel, zinc and phosphorus by a wt % proportion of 94:8:8. The UBM layer 50 favors a fine-quality tin-based solder ball 70 to be formed on the metal pad 20. The tin-based solder ball 70 is then joined with a common-use unleaded tin-based solder alloy, namely SAC305 (Sn—3.0 wt. % Ag—0.5 wt. % Cu). The micrograph is shown in FIG. 5. The fine-quality tin-based solder ball 70 formed on the chip 30 can satisfy the requirement of flip chip package.

In conclusion, the present invention discloses a metallization layer structure for flip chip package. The present invention does not adopt the conventional Au/Ni—P coated layer as the UBM layer and thus is exempt from using expensive gold material and gold-plating equipment. Therefore, the present invention can greatly reduce the cost. Further, the NiZnP coated layer of the present invention is hard to shatter, hard to peel off and highly corrosion-resistant. Moreover, the present invention needs only a single coating process and thus is easy to fabricate, which can further reduce the cost and promote yield.

What is claimed is:

1. A metallization layer structure for flip chip package, which is formed on a metal pad, wherein the metal pad is formed on a chip, and wherein a passive protective layer protects the chip and exposes the metal pad, and the metallization layer comprises
an under-bump metallization layer being a nickel-zinc-phosphorus layer coated on the metal pad.

2. The metallization layer structure for flip chip package according to claim 1, wherein the under-bump metallization layer is the nickel-zinc-phosphorus layer formed via the reduction and oxidization of a solution including nickel sulfate (Ni₂SO₄), zinc sulfate (ZnSO₄), sodium dihydrogen phosphite (NaH₂PO₂), sodium citrate dihydrate (Na₃C₆H_{S}O₇-2H₂O), and ammonium chloride (NH₄Cl).

3. The metallization layer structure for flip chip package according to claim 2, wherein each liter of the solution includes 40 g of Ni₂SO₄, 3 g of ZnSO₄, 11 g of NaH₂PO₂, 60 g of Na₃C₆H_{S}O₇-2H₂O, and 80 g of NH₄Cl.

4. The metallization layer structure for flip chip package according to claim 1 further comprising an adhesion layer formed on the metal pad, wherein the under-bump metallization layer is formed on the adhesion layer and integrated with the metal pad via the adhesion layer.

5. The metallization layer structure for flip chip package according to claim 1, wherein the metal pad is selected from a group consisting of an aluminum pad and a copper pad.

6. The metallization layer structure for flip chip package according to claim 1, wherein the under-bump metallization layer is a NiZnP coated layer including nickel, zinc and phosphorus by a wt % proportion of 94:8:8.
